(19) United States
(12) Patent Application Publication
(10) Pub. No.: US 2010/0040128 A1
(43) Pub. Date: Feb. 18, 2010

(54) Equalizer and Method for Processing a Signal and Communication Receiving System Comprising the Same

(75) Inventor: Yih-Ming Tsuie, Hsinchu City (TW)

Correspondence Address: GROSSMAN, TUCKER, PERREAULT & PFLEGER, PLLC, 55 SOUTH COMMERICAL STREET, MANCHESTER, NH, 03101, US

(73) Assignee: MEDIATEK INC., Hsinchu (TW)

(21) Appl. No.: 12/192,302

(22) Filed: Aug. 15, 2008

(51) Int. Cl. H03H 7/40; H03D 1/04; H04B 1/10; H03H 7/30

(52) U.S. Cl. 375/232; 375/235; 375/346

(57) ABSTRACT

A communication receiving system, an equalizer, and a method for mitigating a burst noise effect of a signal are provided. The equalizer is configured to compensate the signal received from a communication channel. The communication receiving system comprises a receiver, the equalizer, and a detection module. The receiver transmits the signal to the equalizer after receiving the signal. The equalizer compensates the signal and adapts its weighting factors by modifying a correction term upon detection of burst noise. Thereby, the burst noise effect of the signal is mitigated, and the probability that the equalizer survives the burst noise condition increases. Thus, the quality of communication systems under burst noise cases may be enhanced under without increasing the complexity of hardware.

### CROSS-REFERENCES TO RELATED APPLICATIONS

This application is cross-referenced with U.S. patent application Ser. No. 11/752,440 entitled “System and Method of Detecting Burst Noise and Minimizing the Effect of Burst Noise” filed on May 23, 2007.

### BACKGROUND OF THE INVENTION

1. Field of the Invention

The present invention relates to an equalizer and a method for processing a signal and a communication receiving system comprising the same. More particularly, the present invention relates to an equalizer and a method that calculate a correction term in order to mitigate the burst noise effect of a signal and a communication receiving system comprising the same.

2. Descriptions of the Related Art

Communication techniques have been rapidly developed in recent years. However, the current technique still face the difficulties of thoroughly eliminating interferences introduced during transmission. Interferences are usually caused by noises, and interferences become severe when it comes to burst noises. In the digital communication, such as cable system or other communication field, in addition to the semi-static multi-path propagation environment, the burst noises may occur due to lightening, electric switch, or other related factors.

FIG. 1A illustrates a constellation diagram for 256-Quadrature Amplitude Modulation (QAM) at a receiving end with the absence of burst noises. In FIG. 1A, the dots represent received QAM symbols, the horizontal axis denotes the real part (i.e. signals from I-channel) of the received QAM symbols, and the vertical axis denotes the imaginary part (i.e. signals from Q-channel) of the received QAM symbols. The I-channel and the Q-channel are familiar to people skilled in the art, so their detailed descriptions are omitted for brevity. Since there are no burst noises, the values of the received QAM symbols are closed to the transmitted values. The phenomenon may be seen from FIG. 1A, wherein each of the dots is formed almost orderly as a 16-by-16 array.

FIG. 1B illustrates that a constellation diagram for 256-QAM modulation at a receiving end with the presence of burst noises. Similarly, the dots represent received QAM symbols, the horizontal axis denotes the real part of the received QAM symbols, and the vertical axis denotes the imaginary part of the received QAM symbols. Compared with FIG. 1A, the values of the received QAM symbols in FIG. 1B are not closed to the transmitted values. The burst noise phenomenon makes the receiver having difficulties in measuring the original transmitted values from the received QAM symbols. Meanwhile, long-period of burst noise might diverge from the receiving parameters and cause system failures.

To recover the original information from the received data corrupted by burst noises, most developers focus on developing decoding algorithms that can corporate with hardware. For example, a de-interleaver and a Forward Error Correction (FEC) algorithm are utilized to integrate into a demodulator. However, the effectiveness of the aforementioned prior arts is based on the assumption that demodulation subsystems, such as synchronization modules and equalizer, maintain proper reception conditions. Merely focusing on a de-interleaver or FEC may not guarantee proper recovery of the original signal. For example, under the condition of occurrence of long burst noise, the equalizer coefficients might be corrupted due to misled adaptation and cannot be automatically recovered for its proper function even after the occurrence of burst noise. This crashes the communication session, and the only way to rebuild the communication is to reboot the receiver with sensible boot-up time.

Accordingly, it is urgent in this field to find an approach for mitigating the effect of burst noise and design a robust equalizer while considering the fact of the burst noise to enhance communication quality.

### SUMMARY OF THE INVENTION

An objective of this invention is to provide an equalizer for processing a signal received from a communication channel. The equalizer comprises a first calculation module, a determination module, and a second calculation module. The first calculation module is configured to calculate a correction term related to the signal in response to a noise effect of the signal, wherein the correction term comprises a decision error. The determination module is configured to determine the correction term by comparing the decision error of the correction term with a predetermined threshold. The second calculation module is configured to calculate a plurality of weighting factors according to the determined correction term, wherein the weighting factors are used to mitigate the noise effect of the signal. By having the configurations, the equalizer may process the signal from the communication channel without the increase of the complexity in terms of hardware implementation.

Another objective of this invention is to provide a method for processing a signal received from a communication channel. The method comprises the steps of calculating a calculated term related to the signal in response to a noise effect of the signal, wherein the correction term comprises a decision error; determining the correction term according to the decision error in the correction term, and calculating a plurality of weighting factors according to the determined correction term, wherein the weighting factors are used to mitigate the noise effect of the signal. By having the steps, the method is able to mitigate the effect caused by the burst noise. As a result, communication quality is enhanced without increase of the complexity in terms of hardware implementation.

Yet a further objective of this invention is to provide a communication receiving system. The communication receiving system comprises a receiver, a detection module, and an equalizer. The receiver is configured to receive a signal from a communication channel. The detection module is configured to detect a noise effect of the signal. The equalizer is configured to calculate a correction term related to the signal, determine a decision error of the correction term being greater than a predetermined threshold, replacing the decision error if the decision error is greater than the predetermined threshold by a replacing threshold, to calculate a plurality of weighting factors according to the determined correction term, and to calculate a noise-mitigated output signal by convolving the signal and the weighting factors. As a result, the noise effect of the signal can be mitigated by the use of the weighting factors.

According to the aforementioned description, the present invention calculates a correction term to adjust a plurality of weighting factors that are used to mitigate noise effect of a signal. Since weighting factors have been adjusted, noise effect of the signal can be mitigated more thoroughly. As a result, communication qualities can be enhanced without increase of the complexity in terms of hardware implementation.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A illustrates a constellation diagram for 256-QAM modulation at a receiving end with the absence of burst noises;

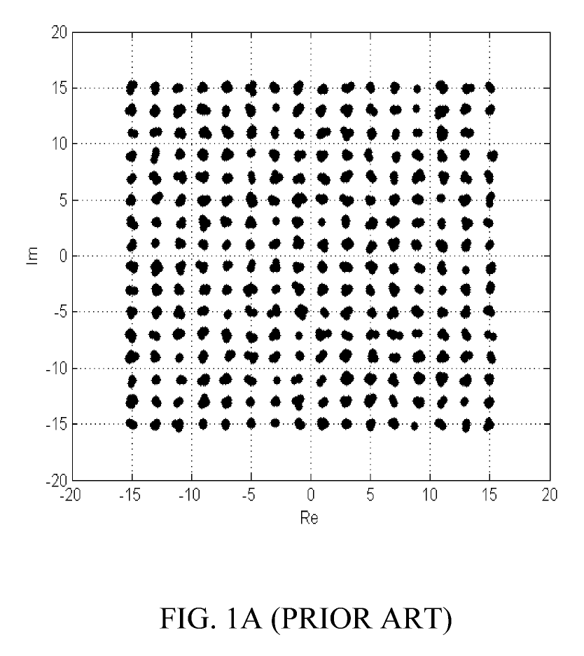

FIG. 1B illustrates a constellation diagram for 256-QAM modulation at receiving end with the presence of burst noises;

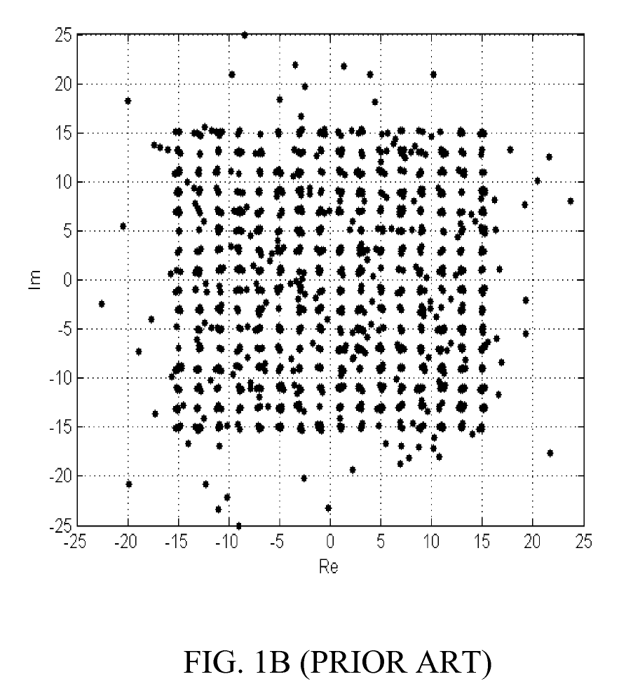

FIG. 2 illustrates an embodiment of a communication receiving system of the present invention;

FIG. 3 illustrates a block diagram of the equalizer of the communication receiving system; and

FIG. 4 illustrates an embodiment of this invention, which is a method for processing a signal received from a communication channel.

### DESCRIPTION OF THE PREFERRED EMBODIMENT

The detailed description of embodiments of the present invention, which relates to an equalizer and a method for mitigating the burst noise effect in a signal and a communication receiving system comprising the same, is provided. However, these embodiments are not intended to limit that this invention can only be embodied in any specific context and applications described in these embodiments. Therefore, descriptions of these embodiments are only intended to illustrate rather than to limit this invention. It should be noted that elements not related to this invention are omitted from depiction in the following embodiments and attached drawings. In this description, two-dimensional signal format is assumed but not limited.

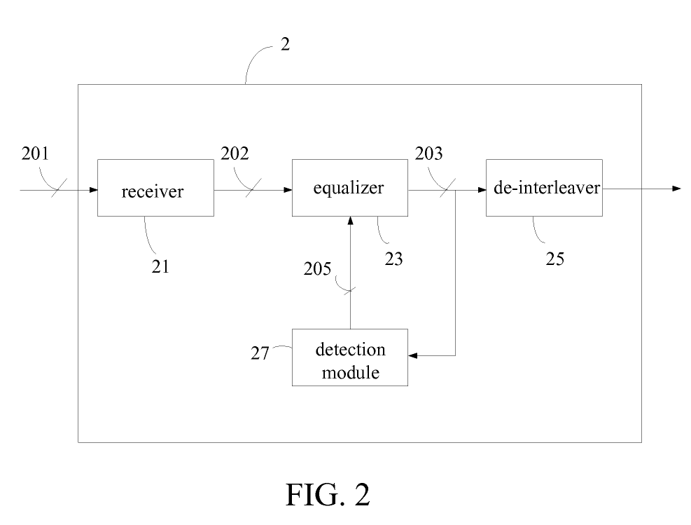

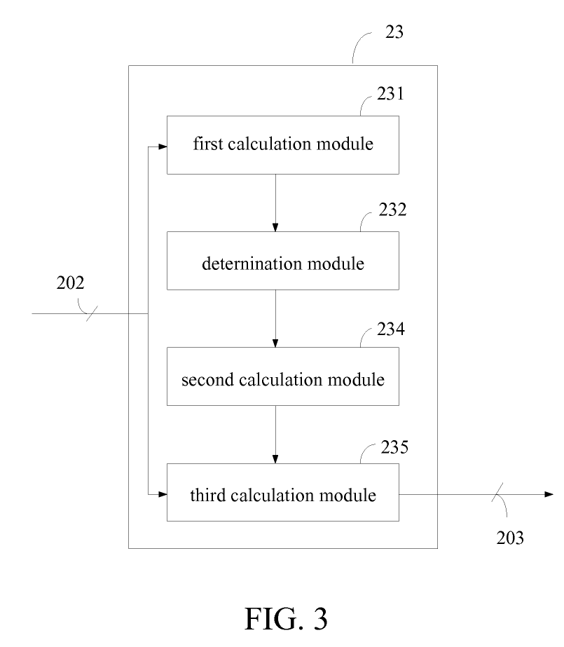

FIG. 2 depicts an embodiment of a communication receiving system 2 of the present invention. The communication receiving system 2 comprises a receiver 21, an equalizer 23, a detection module 27, and a de-interleaver 25. FIG. 3 illustrates a block diagram of the equalizer 23, which comprises a first calculation module 231, a determination module 232, a second calculation module 234, and a third calculation module 235.

The receiver 21 receives a signal 201 from a communication channel. In this embodiment, the signal 201 is analog, so the receiver 21 further converts the signal 201 into a digital signal 202. In digital signal 202, synchronization processing is assumed. The received signal 201 suffers from various kinds of distortion during transmission, such as channel effect, background noise, and burst noise. Therefore, as the digital signal 202 is generated from the signal 201, the distortion effect is still remained.

The equalizer 23, and the detection module 27 form a loop. Thus, the equalizer 23 is able to process the digital signal 202 with the assistance of previous processed results.

The equalizer 23 is aimed to compensate the digital signal 202 (i.e. a signal related to the signal 201) for the communication channel distortion. More specifically, the equalizer 23 adjusts its weighting factors to achieve the compensation. In this embodiment, the equalizer 23 uses the following update equation to update the weighting factors.

W(n+1)=W(n)+αX(n)e*(n) (1)

wherein n denotes the time instant, W(n) represents the present weighting factors, W(n+1) represents the next weighting factors, X(n) represents the input signal vector of the equalizer, α is a constant and often called as the step-size, and e*(n) is a complex conjugate of a decision error e(n). It is noted that the decision error e(n) is fedback from the detection module 27. In this embodiment, the decision error is a vector. The details will be described later.

In the above update equation for weighting factors, αX(n)e*(n) is called a correction term, which leads the weighting factors to the right setting for channel equalization. From the update equation, it is known that the correction term αX(n)e*(n) comprises a decision error e(n). The key to compensate the digital signal 202 more accurately relies on the accuracy of the correction term αX(n)e*(n). This correction term is more error-prone in burst noise cases. In order to derive suitable correction term αX(n)e*(n) in the presence of burst noise, the equalizer 23 works on the decision error e(n) of the correction term αX(n)e*(n).

After receiving the signal 201 and converting the signal 201 into the digital signal 202, the first calculation module 231 calculates the present correction term ( i.e. αX(n)e*(n) ) in response to the multipath and noise effects, i.e. in response to the noise effect of the signal.

Upon detecting the presence of burst noise (see U.S. Ser. No. 11/752,440), after the present correction term (i.e. αX(n)e*(n)) is calculated, the determination module 232 determines whether this correction term is needed to be modified according to the decision error. In the present invention, there are two approaches proposed. One is constraining approach, and the other is nullifying approach. For both approaches, the determination module 232 determines the correction term by comparing the decision error with a predetermined threshold.

Specifically, for the constraining approach, the determination module 232 determines whether the value of the decision error is greater than the value of the predetermined threshold vector. For example, the determination module 232 determines whether an x-directional (horizontal direction) value of the decision error e(n)=(x,y) is greater than an x-directional value of the predetermined threshold. When the absolute value of x (i.e. the x-directional value of the decision error) is not greater than (i.e. less than or equal to) the x-directional value of the predetermined threshold, the determination module 232 of the equalizer 23 does not make changes to the x-directional value of the decision error; that is, remains unchanged. On the contrary, when the determination module 232 determines that the absolute value of x (i.e. x-directional value of the decision error) is greater than the x-directional value of the predetermined threshold, the determination module 232 replaces the x-directional value of the decision error with an x-replacing value of a predetermined replacing vector. In this embodiment, the x-replacing value of the predetermined replacing vector is related to the predetermined threshold. For example, the x-replacing value may be calculated by multiplying the absolute value of the x-directional value of the predetermined threshold with the sign of the original x-directional value of the decision error. The same procedure applies to a y-directional value of the decision error as well. In addition, the predetermined threshold, being a vector, defines the normal level of tolerance of burst noise. If the value of the decision error vector is greater than the value of the predetermined threshold, this means the burst noise is quite large.

For the nullifying approach, if either the absolute value of the x-directional value of the decision error is greater than the x-directional value of the predetermined threshold or the absolute value of the y-directional value of the decision error is greater than the y-directional value of the predetermined threshold, the determination module 232 may replace the decision error with the vector of (0,0). Otherwise, the x-directional or y-directional of the decision error remains as the original value. This is saying that the decision error is set to be (0,0) while the burst error is quite large. After the decision error is updated, the second calculation module 234 updates the weighting factors from W(n) to W(n+1), which is to be used to process the next input vector X(n+1). More specifically, the second calculation module 234 first calculates the updated correction term αX(n)<e*(n)>, wherein <e*(n)> is now with the value of the updated decision error generated from the determination module 232. Then, the second calculation module 234 adds the update term αX(n)<e*(n)> to W(n) to derive W(n+1), that is

W(n+1)=W(n)+αX(n)<e*(n)>

In addition, for the case of there is no burst noise and for the case that determining there is no need to modify the decision error after the result of comparing to threshold as mentioned above, the determination module 232 forwards the correction term to the second calculation module 234 for generating W(n+1), that is

W(n+1)=W(n)+αX(n)e*(n)

Then, the third calculation module 235 for calculating the noise-mitigated output signal 203 by convolving the digital signal 202 with the burst-noise-mitigated weighting factors W(n+1). Thereafter, the equalizer 23 output signal 203 is transmitted to the de-interleaver 25 for de-interleaving. The de-interleaver 25, FEC processing is usually added for channel decoding purpose. The functions and the operations of the de-interleaver 25 are well-known to people skilled in the art, so the detailed description is omitted here for brevity.

The detection module 27 receives the equalizer 23 output signal 203 from the equalizer 23 and produces results in order to calculate the decision error e(n). The equalizer 23 output signal 203 from the equalizer 23 is denoted as y(n). The detection module 27 performs a decision on the equalizer 23 output signal 203 by comparing y(n) with decision boundaries. It should be noted that the boundaries are designed according to various modulation types. There are decisions d(n) located in the different the decision boundaries. Once the detection module 27 detects which region, separated by the boundaries, is the y(n) belongs to, the detection module 27 assigns the decision result d(n) which can be used to calculate the decision error e(n). The decision error e(n) is derived by the equation: e(n)=d(n)−y(n). The decision error e(n) can be fedback to the equalizer 23 for equalizing the weighting factors and then updating processing. It should be noted that the subtracting step for generating e(n) may be done in the detection module 27, in this case the detection module output 205 comprise the decision error e(n). In the other embodiments, e(n) can be produced in the equalizer 23 and in this case the detection module output 205 denotes the decision result d(n).

It is noted that the receiver 21, the de-interleaver 25, and the detection module 27 are familiar to people skilled in the art, so only those related to the present invention are described. The receiver 21 may comprise analog to digital converter and synchronization module in practice. The equalizer 23 of the communication receiving system 2 is able to work with other receivers, de-interleaver, and detection module. The detection module 27 for detecting the burst noise may be referred to the patent application Ser. No. 11/752,440 or other method for detecting the burst noise known by one who has skill in the relevant art.

According to the aforementioned arrangement, upon detecting the presence of burst noise, this embodiment calculates the correction term to adjust the weighting factors that are used to mitigate the burst noise impact on channel equalization of the digital signal 202. Since burst noise effect on weighting factors have been mitigated, the possibility that the equalizer survives the burst noise impact increases. As a result, communication qualities can be enhanced without increase of the complexity in terms of hardware implementation.

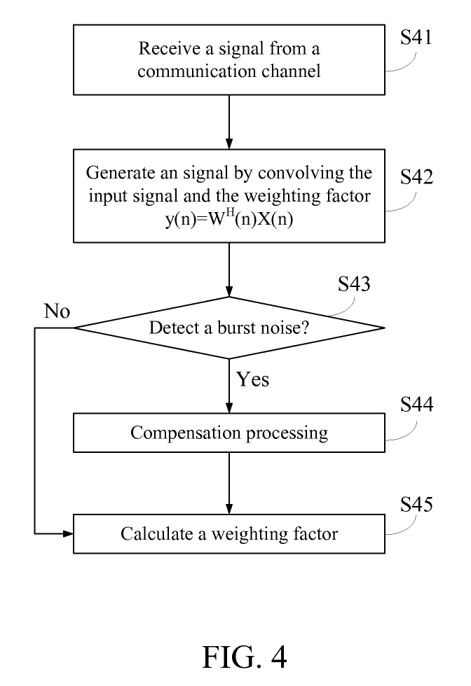

FIG. 4 depicts a method for processing a signal of the exemplary embodiment of the present invention, wherein the signal x(n) is received from a communication channel. The method is used to mitigate the burst noise effect in the signal. Initially, the method executes step S41 to receive the signal from a communication channel. Then, step S42 is executed to generate an equalizer output signal by convolving the input signal and the weighting factor. More specifically, step 42 may use the equation y(n)=W^{H}(n)X(n), wherein W(n) is a weighting factor vector and X(n) is the input signal vector. Then, a decision error e(n) is generated either in the detection module 27 or equalizer 23, wherein the decision error e(n) is a vector. The detection module 27 also determines whether the burst noise is occurred as the step S43. If there is no existence of the burst noise, the decision error is no need to be calculated and goes directly to step 45 to calculate a plurality of weighting. Otherwise (i.e. the result of step S43 is no), the decision error is calculated and compare to the predetermined threshold to decide whether to adjust e(n). Next, the method executes step S44 for compensation processing to compare an x-directional value of the decision error with an x-directional value of a predetermined threshold if the burst noise is detected, wherein the predetermined threshold is also a vector. There are two proposed approaches, the constraining and nullifying approaches, for deciding how to replace the decision error e(n)=(x,y) in the present invention. For the constraining approach, x (i.e. the x-directional value) remains unchanged if the absolute value of x is less than the horizontal directional value of the predetermined threshold (herein refers as x-threshold value), and y (i.e. the y-directional value) remains unchanged if the absolute value of the y is less than the vertical directional value of the predetermined threshold (herein refers as y-threshold value). While x is greater than the x-threshold value, x is to be replaced with a replacing value. Similarly, while y is greater than the y-threshold value, y is to be replaced with another replacing value. Those two replacing values form a vector. The replacing vector may be related to the pre determined threshold. For example, x may be replaced with the absolute value of x-threshold value with the original sign of x and y may be replaced with the absolute value of y-threshold value with the original sign of y. In addition, the threshold vector defines the normal level of tolerance of burst noise. While the decision error is greater than the predetermined threshold, this implies the burst noise is quite large. For nullifying approach, if the absolute value of x is greater than the x-threshold value or the absolute value of y is greater than y-threshold value, the decision error is set to be (0,0). If the absolute value of x is less than the x-threshold value and the absolute value of y is less than the y-threshold value, the decision error is not changed. The step S44 generates the updated decision error. A correction term related to the signal in response to the noise effect of the signal is calculated. More specifically, the signal is received continuously, so the noise effect is detected from a previous time instant.

After that, step S45 is executed to calculate a plurality of weighting factors according to the updated correction term from step S44 or calculate a plurality of weighting factor directly from step S43. If the decision error is less than the predetermined threshold, the method executes step S45 directly.

In addition to the above steps, this embodiment is able to execute all the operations and functions as those described in the embodiment of the communication receiving system. Those skilled in the art can directly understand how this embodiment can execute the operations and functions based on the aforementioned embodiment of the communication receiving system. Consequently, redundant descriptions for the operations and functions are not repeated herein.

In summary, this invention provides a communication receiving system, an equalizer, and a method for eliminating a noise effect of a signal received from a communication channel. By adjusting the correction term used in the equalizer, the noise effect can be better mitigated. Thus, the quality of communication systems can be enhanced without increase of the complexity in terms of hardware implementation.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A method for processing a signal received from a communication channel, comprising the steps of:
calculating a correction term related to the signal in response to a noise effect of the signal, wherein the correction term comprises a decision error;
determining the correction term according to the decision error; and
calculating a plurality of weighting factors according to the determined correction term, wherein the weighting factors are utilized to mitigate the noise effect of the signal.

2. The method of claim 1, further comprising a step of calculating a noise-mitigated output signal by convolving the signal and the weighting factors.

3. The method of claim 1, wherein the step of determining the correction term according to the decision error compares the decision error with a predetermined threshold.

4. The method of claim 1, wherein the decision error is a vector, and when an x-directional value of the decision error is less than an x-directional value of a predetermined threshold, the x-directional value of the decision error remains unchanged.

5. The method of claim 4, wherein the x-directional value of the decision error being less than the x-directional value of the predetermined threshold is determined by comparing the absolute value of the x-directional value of the decision error with the x-directional value of the predetermined threshold.

6. The method of claim 1, wherein the decision error is a vector, and when an x-directional value of the decision error is greater than an x-directional value of a predetermined threshold, the x-directional value of the decision error is replaced with an x-replacing value.

7. The method of claim 6, wherein the x-replacing value is calculated by multiplying the absolute value of the x-directional value of the predetermined threshold with the sign of the x-directional value of the decision error.

8. The method of claim 1, wherein when one of an x-directional value of the decision error being greater than an x-directional value of a predetermined threshold and an y-directional value of the decision error being greater than an y-directional value of the predetermined threshold happens, both the x-directional value and y-directional value of the decision error are set to be 0.

9. The method of claim 1, wherein the calculating step calculates the weighting factors by adding the determined correction term to the weighting factors.

10. An equalizer for processing a signal received from a communication channel, the equalizer comprises:
a first calculation module for calculating a correction term related to the signal in response to a noise effect of the signal, wherein the correction term comprises a decision error;
a determination module for determining the correction term by comparing the decision error with a predetermined threshold;
a second calculation module for calculating a plurality of weighting factors according to the determined correction term, wherein the weighting factors are used to mitigate the noise effect of the signal.

11. The equalizer of claim 10, further comprising a third calculation module for calculating a noise-mitigated output signal by convolving the signal and the weighting factors.

12. The equalizer of claim 10, wherein the decision error is a vector, and when an x-directional value of the decision error is less than an x-directional value of the predetermined threshold, the determination module determines that the x-directional value of the decision error remains unchanged.

13. The equalizer of claim 10, wherein the decision error is a vector, and when an x-directional value of the decision error is greater than an x-directional value of the predetermined threshold, the determination module replaces the x-directional value of the decision error with an x-replacing value.

14. The equalizer of claim 13, wherein the x-replacing value is calculated by multiplying the absolute value of the x-directional value of the predetermined threshold with the sign of the x-directional value of the decision error.

15. The equalizer of claim 10, wherein when one of an x-directional value of the decision error being greater than an x-directional value of the predetermined threshold and an y-directional value of the decision error being greater than an y-directional value of the predetermined threshold happens, the determination module sets both the x-directional value and y-directional value of the decision error to 0.

16. The equalizer of claim 10, wherein the second calculation module calculates the weighting factors by adding the determined correction term to the weighting factors.

17. A communication receiving system, comprising:
a receiver for receiving a signal from a communication channel;
a detection module for detecting a noise effect of the signal; and
an equalizer for calculating a correction term related to the signal, for determining a decision error of the correction term being greater than a predetermined threshold, for determining the decision error by a replacing threshold, for calculating a plurality of weighting factors according to the determined correction term, and for calculating a noise-mitigated output signal by convolving the signal and the weighting factors,
wherein the weighting factors is used to mitigate the noise effect of the signal.

18. The communication receiving system of claim 17, further comprising a de-interleaver for de-interleaving the noise-mitigated output signal.

19. The communication receiving system of claim 17, wherein the decision error is a vector, and when an x-directional value of the decision error is less than an x-directional value of the predetermined threshold, the equalizer decides the x-directional value of the decision error remains unchanged.

20. The communication receiving system of claim 17, wherein the decision error is a vector, and when an x-directional value of the decision error is greater than an x-directional value of the predetermined threshold, the equalizer replaces the x-directional value of the decision error with an x-replacing value.

21. The communication receiving system of claim 20, wherein the x-replacing value is calculated by multiplying the absolute value of the x-directional value of the predetermined threshold with the sign of the x-directional value of the decision error.

22. The communication receiving system of claim 17, wherein one of an x-directional value of the decision error being greater than an x-directional value of the predetermined threshold and an y-directional value of the decision error being greater than an y-directional value of the predetermined threshold happens, the determination module sets both the x-directional value and y-directional value of the decision error to 0.

23. The communication receiving system of claim 17, wherein the equalizer calculates the weighting factors by adding the determined correction term to the weighting factors.
